(19) United States
(12) Patent Application Publication
(10) Pub. No.: US 2004/0087145 A1
(43) Pub. Date: May 6, 2004

(54) Semiconductor device and method of manufacturing

(76) Inventors: Ian Dale, Lincoln (GB); Michael W Carr, Lincoln (GB); Robert J Foulger, Lincoln (GB)

Correspondence Address: Kirschstein Ottinger, Israel & Schiffmiller, 489 Fifth Avenue, New York, NY, 10017-6105, US

(21) Appl. No.: 10/311,628

(22) PCT Filed: Jun. 28, 2001
(86) PCT No.: PCT/GB01/02849

(30) Foreign Application Priority Data
Jun. 28, 2000 (GB) 0015775.0

(51) Int. Cl. H01L 21/44

(52) U.S. Cl. 438/684

(57) ABSTRACT

A method of manufacturing a semiconductor device includes the steps of: taking a semiconductor wafer (8); defining non-conductive region (11) and a conductive region (15) providing electrical contact means (10) at the conductive region; and separating the wafer into a plurality of dies. By using wafer scale fabrication, thousands of devices may be packaged simultaneously in single process steps without significant operator intervention compared to the conventional packaging processes. An insulating wafer (12) may be located over the semiconductor wafer and bonded thereto, the insulating wafer having a plurality of tapered apertures (13) therethrough which are aligned with conducting regions of the semiconductor wafer.

This invention relates to semiconductor packaging, and more particularly, but not exclusively, to packaging of a Gunn diode, such as is used in automotive radar systems as a radiation source.

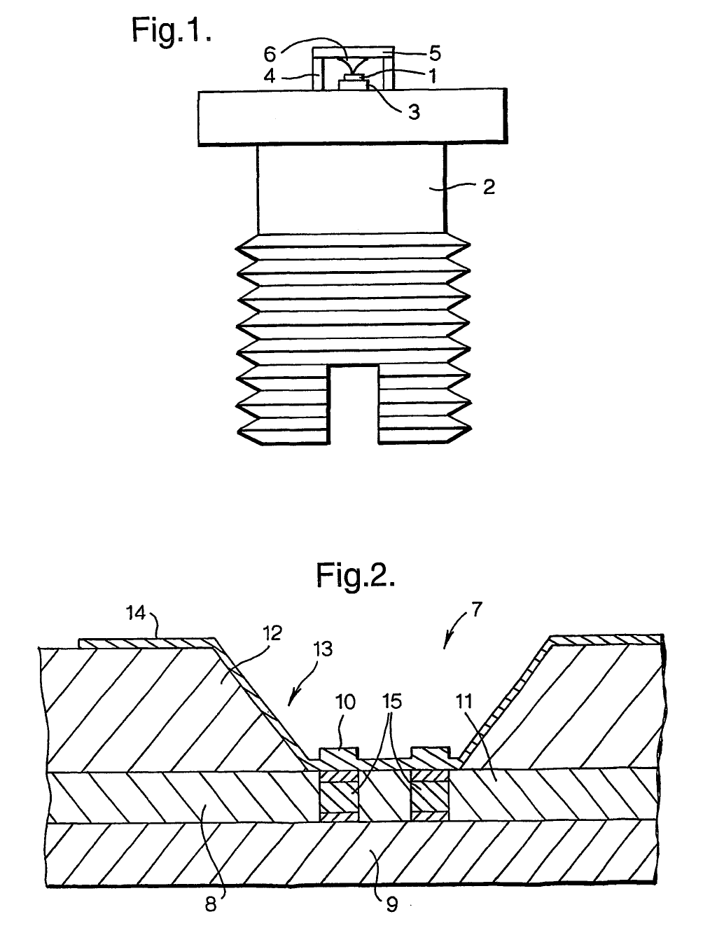

One previously known arrangement for encapsulating a semiconductor device such as a Gunn diode is schematically illustrated in FIG. 1, which is a transverse section through a Picopill package. This is an industry standard encapsulation for a semiconductor die 1. It includes a threaded main body 2 of gold plated copper which is relatively massive and has a small cylindrical pedestal 3 projecting from its upper surface as shown. A cylindrical ceramic ring 4 is brazed to the top surface of the main body 1 and surrounds the pedestal 3. The semiconductor die 1 is located on the pedestal 3 and is surrounded by the ceramic ring 4. A gold plated kovar cap 5 is brazed to the upper surface of the ceramic ring 4 to seal the package. Electrical connection is made to the semiconductor die via thin gold leads 6 between the die 1 and the cap 5. In use, a dc voltage is applied between the cap 5, which acts as the anode, and the main body 2 which is the cathode. Assembly of the components is a skilled, labour intensive operation and the actual components are relatively expensive, and thus the resultant encapsulated devices are also expensive.

The present invention arose when considering how the manufacture of Gunn diodes in particular could be improved.

According to a first aspect of the invention, a method of manufacturing a semiconductor device includes the steps of: taking a semiconductor wafer; defining a non-conductive region and a conductive region; providing electrical contact means at the conductive region; and separating the wafer into a plurality of dies.

The invention is particularly applicable to the manufacture of diode devices and more particularly to Gunn diodes. By using wafer scale fabrication, thousands of devices may be packaged simultaneously in single process steps without significant operator intervention compared to the conventional packaging processes. For example, the electrical contacts for all the diodes derived from a common wafer may be laid down in a single step. The need to enclose a die in the surrounding ceramic component with a cap and attach the fine gold leads is completely avoided. The manufacture of individual components, such as the cap and ceramic ring, for later assembly is not required.

The electrical contact means may be provided prior to the conductive and non-conductive regions being defined. In that case, the electrical contact means may be used as a mask to shield one region during a processing step. This enables automatic registration to be achieved between an electrical connection to the conductive region and the volume occupied by that region. In one preferred method, the non-conductive region is defined using ion implantation, but other techniques may be used.

In one advantageous step, an insulating wafer is located over the semiconductor wafer and bonded thereto, the insulating wafer having a plurality of apertures therethrough which are aligned with conducting regions of the semiconductor wafer. Part of the electrical contact means may then be laid down on the insulating wafer. This provides a relatively large conductive area around the active part of the final device which may be readily connected to circuitry or conductive tracks or leads. Preferably, the apertures in the insulating wafer have tapered sides, thereby facilitating the deposition of a conductive layer for connection to the conductive region of the semiconductor wafer.

According to a second aspect of the invention, a semiconductor diode comprises a semiconductor material having a conductive region and a surrounding non-conductive region, with a layer of electrically insulating or semi-insulating material over the non-conducting region and electrical contact means extensive over a surface of the conductive region and the layer. Preferably the diode is a Gunn diode.

A diode in accordance with the second aspect is particularly robust compared to previously available devices in which unsupported bond leads are required for connection to the diode. The invention also leads to ease of handling during shipping of products, incorporation into circuits and in use, even where products are used in environments experiencing considerable vibration, for example. Devices in accordance with the invention are thus particularly suitable for use in high volume consumer products. The layer may, for example, be of glass or ceramic, or could be of a semi-insulating material, such as a semi-insulating gallium arsenide material.

One way in which the invention may be performed is now described by way of example with reference to the accompanying drawing, in which:

FIG. 2 schematically shows a packaged semiconductor device in accordance with the invention.

With reference to FIG. 2, a Gunn die 7 is shown in schematic cross section. It is only one structure of many thousands of other similar structures formed on a single semiconductor wafer 8, which in this case is of gallium arsenide.

In the manufacturing process, firstly the wafer 8 is electroplated on its lower surface and chemically thinned to a few microns thickness to give an electrical contact 9 and heat sink. Then, for each Gunn die on the wafer, a second annular electrical contact 10 is laid down on the upper surface of the wafer 8. The wafer is subsequently exposed to ion bombardment to render those regions not under the annular contact 10 electrically insulating, this implant isolation region being shown as 11. An insulating wafer 12, for example of glass or ceramic, having an array of tapered holes 13 therethrough, is then bonded to the semiconductor wafer 8 with the annular contacts 10 serving as an aid to registration, the holes 13 being aligned with the contacts 10. Another layer of metallisation 14 is then deposited on the upper surface of the insulating wafer 12 and connects with the annular contacts 10. Finally the individual dies are separated out using standard dicing techniques. The implant isolation region 11 provides lateral shielding around the part of the semiconductor wafer 8 not exposed to the ion bombardment, this undamaged region 15 being an annular transit region in the finished device.

In another method, a layer of semi-insulating material is used instead of using a separately fabricated glass or ceramic wafer. This may be, for example, semi-insulating gallium arsenide which is formed as a constituent part of the original gallium arsenide wafer. In that case, via-holes are etched through the semi-insulating material to reveal the conductive regions of the semiconductor wafer.

In another embodiment, not shown, the transit region of the Gunn die has a circular cross sectional area instead of the annular configuration shown in FIG. 2.

1. A method of manufacturing a semiconductor device including the steps of:
taking a semiconductor wafer; defining a nonconductive region and a conductive region; providing electrical contact means at the conductive region; and separating the wafer into a plurality of dies.

2. A method as claimed in claim 1, in which the electrical contact means includes a mask for shielding a region of the wafer during the step of defining the non-conductive region and the conductive region.

3. A method as claimed in claim 1 or 2, in which the non-conductive region is defined by means of ion implantation.

4. A method as claimed in any preceding claim, further comprising the step of bonding an at least partially insulating wafer to the semiconductor wafer.

5. A method as claimed in claim 4, in which the insulating wafer has an aperture arranged to align with the conductive region.

6. A method as claimed in claim 5, in which the aperture is tapered.

7. A method as claimed in claim 4, 5 or 6, further comprising the step of laying down part of the electrical contact means on the insulating wafer

8. A method as claimed in any one of claims 4 to 7, in which the at least partially insulating wafer includes glass material.

9. A method as claimed in any one of claims 4 to 7, in which the at least partially insulating wafer includes gallium arsenide.

10. A method as claimed in any one of claims 4 to 7, in which the at least partially insulating wafer includes ceramics material.

11. A method, substantially as hereinbefore described, with reference to the accompanying drawings.

12. A semiconductor diode manufactured by a method as claimed in any preceding claim.

13. A semiconductor diode comprising a semiconductor material having a conductive region and a surrounding non-conductive region, with a layer of at least partially insulating material over the non-conducting region and electrical contact means extensive over a surface of the conductive region and the layer.

14. A semiconductor diode, substantially as hereinbefore described, with reference to, or as illustrated in FIG. 2 of the accompanying drawings.
